(19) United States
(12) Patent Application Publication
(10) Pub. No.: US 2018/0159461 A1
(43) Pub. Date: Jun. 7, 2018

(54) Solar Photovoltaic Power Systems

(71) Applicants: Lear Lavi, Laguna Niguel, CA (US); Bijan Pakray, Foothill Ranch, CA (US)

(72) Inventors: Lear Lavi, Laguna Niguel, CA (US); Bijan Pakray, Foothill Ranch, CA (US)

(21) Appl. No.: 15/369,631

(22) Filed: Dec. 5, 2016

(51) Int. Cl. H02S 20/10; H02S 99/00; H01L 31/048; H01L 31/0216

(52) U.S. Cl. CPC H02S 20/10; H01L 31/02168; H01L 31/048; H02S 99/00

(57) ABSTRACT

Solar photovoltaic power systems that are also utilized for hardscaping or softscaping or landscaping. Pavers that generates solar power and is used for hardscaping in a solar photovoltaic power system, artificial plants that generates solar power and is used for softscaping in a solar photovoltaic power system, artificial grass that generates solar power and is used for softscaping in a solar photovoltaic power system, and/or any combination of aforementioned pavers, artificial plants, and/or artificial grass that generates solar power and is used for landscaping in a solar photovoltaic power system.

### FIELD OF THE INVENTION

The present invention relates generally to solar photovoltaic power systems that are also utilized for hardscaping, softscaping, or landscaping. The present invention also relates generally to a paver that generates solar power for use as a hardscape in a solar photovoltaic power system. The present invention also relates generally to an artificial plant that generates solar power for use as a softscape in a solar photovoltaic power system. The present invention also generally relates to artificial grass that generates solar power for use as a softscape in a solar photovoltaic power system. Furthermore, the present invention relates generally to any combination of aforementioned paver, artificial plant, and artificial grass for use as a landscape in a solar photovoltaic power system.

### BACKGROUND OF THE INVENTION

Solar power is generated by converting the sun's rays into electricity by exciting electrons in solar cells using the photons of light from the sun. Solar (or photovoltaic) cells convert the sun's energy into electricity. The process of creating electricity relies on the photoelectric effect: the ability of matter to emit electrons when a light is shone on it.

Most solar energy in use today utilize silicon material for the creation of the photoelectric effect. Silicon is what is known as a semi-conductor, meaning that it shares some of the properties of metals and some of those of an electrical insulator, making it a key ingredient in solar cells.

Sunlight is composed of miniscule particles called photons, which radiate from the sun. As these hit the silicon atoms of the solar cell, they transfer their energy to loose electrons, knocking them clean off the atoms freeing up electrons. An electrical imbalance within the cell herds these stray electrons into an electric current.

Creating this imbalance is made possible by the internal organization of silicon. Silicon atoms are arranged together in a tightly bound structure. By squeezing small quantities of other elements into this structure, two different types of silicon are created: N-type, which has spare electrons, and P-type, which is missing electrons, leaving holes in their place.

When these two materials are placed side by side inside a solar cell, the n-type silicon's spare electrons jump over to fill the gaps in the p-type silicon. This means that the N-type silicon becomes positively charged, and the P-type silicon is negatively charged, creating an electric field across the cell. Because silicon is a semi-conductor, it can act like an insulator, maintaining this imbalance. As the photons smash the electrons off the silicon atoms, this field drives them along in an orderly manner, creating electric current.

Solar cells made from silicon are typically manufactured as rigid or flexible panels. Rigid panels are susceptible to damage and this limits the ways in which the solar systems utilizing silicon rigid panels are deployed. As such, solar photovoltaic power systems tied to the grid utilizing solar cells with silicon as the key ingredient has been predominately utilized on rooftop solar systems or on the ground systems in open fields. Another consideration when deploying rigid panels system is that the systems are not visibly pleasing. As such, on the ground solar photovoltaic power systems are typically deployed in unpopulated areas.

More recently, thin film solar cells have been gaining acceptance in solar photovoltaic power systems and are being deployed in a multitude of ways. Thin film solar cells generate electricity much in the same fashion as silicon solar panels. In thin film solar cells, with exposure to light, solar energy is generated by utilizing a “P” type material and an ‘N” type material side by side in much the same fashion as a silicon wafer cell. The thinness of the cell is the defining characteristic of thin film solar cells. Unlike silicon wafer cells, which have light absorbing layers that are traditionally 350 microns thick, thin film solar cells have light absorbing layers that are just one micron thick. This thinness allows thin film solar cells to be more flexible and more durable than silicon wafer cells. One advantage of thin film solar cells over silicon wafer solar cells is that thin film solar cells can be manufactured much more economically than silicon wafer solar cells. One disadvantage of thin film solar cells is that the solar cells are less efficient at converting light energy to solar energy when compared to silicon wafer cells. However, with the recent advances in thin film solar cells, the efficiency of thin film solar cells is approaching that of silicon wafer cells. With the breakthrough in efficiencies of thin film solar cells coupled with low cost manufacturing and flexible and durability characteristics, thin film solar cells can be deployed in ways that could not have been anticipated.

The problems with current solar photovoltaic power systems is the high cost of manufacturing coupled with high installation cost and limitations in dedicated space for deployment. Another problem with current photovoltaic power systems is that the systems are not aestetically pleasing. Due to these problems, current solar photovoltaic power systems have yet to receive widespread adaption.

This present invention relating to solar photovoltaic power systems overcomes the problems in current solar photovoltaic power systems thereby creating an environment for widespread adaptation of solar photovoltaic power systems. In these respects, the solar photovoltaic power systems according to the present invention substantially departs from current conventional and non-conventional concepts and designs and in so doing provides new solar photovoltaic power systems.

### SUMMARY OF THE INVENTION

In view of the foregoing disadvantages inherent in the known types of solar photovoltaic power systems, the present invention provides new solar photovoltaic power systems.

The general purpose of the present invention, which will be described subsequently in greater detail, is to provide new solar photovoltaic power systems that has many of the advantages mentioned heretofore and many novel features that result in new solar photovoltaic power systems which is not anticipated, rendered obvious, suggested, or even implied by any prior art solar photovoltaic power systems, either alone or in any combination thereof.

This present invention comprises of solar photovoltaic power systems consisting of the following:
a.) Pavers that generates solar power and is used for hardscaping in a solar photovoltaic power system.
b.) Artificial plants that generates solar power and is used for softscaping in a solar photovoltaic power system.
c.) Artificial grass that generates solar power and is used for softscaping in a solar photovoltaic power system whereby the artificial grass is manufactured and configured in either one of two methods:
   One method utilizes artificial grass blades manufactured with or containing photovoltaic material.
   Another method utilizes artificial grass blades manufactured with fiber optic material which then overlays one or more solar cells or solar panels.
d.) Any combination of pavers, artificial plants, and/or artificial grass that generates solar power and is used for landscaping in a solar photovoltaic power system.
   Pavers that Generates Solar Power and is Used for Hardscaping

A paver that generates solar power consist of one or more solar cells or solar panels sealed in anti-reflective material and adhered to a top hard surface and a bottom hard surface. The top hard surface provides support and protects the one or more solar cells or panels. The top surface is also manufactured from anti-reflective hard material that allows the transmission of light to the one or more solar cells or panels that lay beneath. The bottom hard surface provides support, rigidity, strength, and weight to the paver and also serves to protect the one or more solar cells or solar panels that lay above. For a paver consisting of a plurality of solar cells or panels, the solar cells or panels are electrically connected in a solar array. A plurality of pavers used for hardscaping are electrically connected in a solar array to create hardscaping that generates solar power. The solar array of pavers are electrically connected to a home or business or utility grid using balance of system (BOS) components creating a solar photovoltaics power system that utilizes hardscaping.

The balance of system encompasses all the components of a solar photovoltaic power system other that the pavers. A solar photovoltaic power system utilizing pavers, depending on the size of the installation, have multiple strings of solar photovoltaic wiring/cables emanating from one or more paver solar arrays and terminate in one electrical box, called a fused array combiner. Contained within the combiner box are fuses designed to protect the individual array cables, as well as the connections that deliver power to the inverter. The electricity produced at this stage is DC (direct current) is converted to AC (alternating current) for suitable use in a home or business. The inverter turns the DC electricity into 120-volt AC that can be put to immediate use by connecting the inverter directly to a dedicated circuit breaker in the electrical panel. If also tied to the utility grid, the DC power is converted into 120/240 volt AC power and fed directly into the utility power distribution system of the building.

Artificial Plants that Generates Solar Power and is Used for Softscaping

An artificial plant that generates solar power consist of one or more artificial leaves that generate solar power. The artificial leaf consist of one or more solar cells or solar panels contained within the geometry of the artificial leaf blade or fabricated in the geometry of the artificial leaf blade. For an artificial leaf consisting of a plurality of solar cells or solar panels, the solar cells or solar panels are electrically connected in a solar array. Protection of the one or more solar cells or solar panels of the artificial leaf is provided by environmental sealing the artificial leaf with an anti-reflective thin film plastic material or anti-reflective sealant. For an artificial plant consisting of a plurality of artificial leaves that generate solar power, the artificial leaves that generate solar power are electrically connected in a solar array. A plurality of artificial plants that generate solar power and used for softscaping are electrically connected in a solar array to create softscaping that generates solar power. The solar array of artificial plants are electrically connected to a home or business or utility grid using balance of system (BOS) components creating a solar photovoltaics power system that utilizes softscaping.

The balance of system encompasses all the components of a solar photovoltaic power system other that the artificial plants. A solar photovoltaic power system utilizing artificial plants, depending on the size of the installation, multiple strings of solar photovoltaic array of conductive wiring/cables emanate from one or more artificial plant solar arrays and terminate in one electrical box, called a fused array combiner. Contained within the combiner box are fuses designed to protect the individual array cables, as well as the connections that deliver power to the inverter. The electricity produced at this stage is DC (direct current) which is converted to AC (alternating current) for suitable use in a home or business. The inverter turns the DC electricity into 120-volt AC that can be put to immediate use by connecting the inverter directly to a dedicated circuit breaker in the electrical panel. If also tied to the utility grid, the DC power is converted into 120/240 volt AC power and fed directly into the utility power distribution system of the building.

Artificial Grass Made from Photovoltaic Grass Blades that Generates Solar Power and is Used for Softscaping.

Artificial grass that generates solar power consist of artificial grass blades consisting of or made from one or more solar cells or solar panels electrically connected in a solar array. For an artificial grass blade consisting of a plurality of solar cells or solar panels, the solar cells or solar panels are electrically connected in a solar array. A plurality of artificial grass blades are electrically connected in a solar array and configured to resemble natural grass. The artificial grass blades are environmentally sealed with anti-reflective thin film plastic material or anti-reflective sealant. The grass blades are adhered to a backing material which provides the solar array electrical connectivity of the blades. The backing material also provides support to the artificial grass blades.

For ease of installation, the artificial grass can be manufactured into modules. A plurality of artificial grass modules that generate solar power and used for softscaping are electrically connected in a solar array to create softscaping that generates solar power. The solar array of artificial grass modules are electrically connected to a home or business or utility grid using balance of system (BOS) components creating a solar photovoltaics power system that utilizes softscaping.

The balance of system encompasses all the components of a solar photovoltaic power system other than the artificial grass modules. A solar photovoltaic power system utilizing artificial grass modules, depending on the size of the installation, have multiple strings of solar photovoltaic array of conductive wiring/cables emanate from one or more artificial grass module solar arrays and terminate in one electrical box, called a fused array combiner. Contained within the combiner box are fuses designed to protect the individual array cables, as well as the connections that deliver power to the inverter. The electricity produced at this stage is DC (direct current) which is converted to AC (alternating current) for suitable use in a home or business. The inverter turns the DC electricity into 120-volt AC that can be put to immediate use by connecting the inverter directly to a dedicated circuit breaker in the electrical panel. If also tied to the utility grid, the DC power is converted into 120/240 volt AC power and fed directly into the utility power distribution system of the building.

Artificial Grass Made from Fiber Optic Grass Blades that Generates Solar Power and is Used for Softscaping.

Artificial grass that generates solar power consist of artificial grass blades made from fiber optic or similar light absorbent material overlaying one or more solar cells or solar panels. The artificial grass is overlaid and adhered to one or more solar cells or solar panels with a light absorbent adhesive material. The artificial grass blades are configured to resemble natural grass. The light absorbent grass blades allow for the transmission of light to the solar cells or panels that lay beneath. The light that is transmitted to the one or more solar cells or solar panels that lay beneath is able to create the photovoltaic effect and generate solar power. A plurality of solar cells or panels that lay beneath the artificial grass blades are electrically connected in a solar array.

For ease of installation, the artificial grass can be manufactured into modules. A plurality of artificial grass modules that generate solar power and used for softscaping are electrically connected in a solar array to create softscaping that generates solar power. The solar array of artificial grass modules are electrically connected to a home or business or utility grid using balance of system (BOS) components creating a solar photovoltaics power system that utilizes softscaping.

The balance of system encompasses all the components of a solar photovoltaic power system other than the artificial grass modules. A solar photovoltaic power system utilizing artificial grass modules, depending on the size of the installation, have multiple strings of solar photovoltaic array of conductive wiring/cables emanate from one or more artificial grass module solar arrays and terminate in one electrical box, called a fused array combiner. Contained within the combiner box are fuses designed to protect the individual array cables, as well as the connections that deliver power to the inverter. The electricity produced at this stage is DC (direct current) which is converted to AC (alternating current) for suitable use in a home or business. The inverter turns the DC electricity into 120-volt AC that can be put to immediate use by connecting the inverter directly to a dedicated circuit breaker in the electrical panel. If also tied to the utility grid, the DC power is converted into 120/240 volt AC power and fed directly into the utility power distribution system of the building.

Any Combination of Pavers, Artificial Plants, and/or Artificial Grass that Generates Solar Power and is Used for Landscaping

Any combination of one or more pavers, one or more artificial plants, and/or one or more artificial grass that generate solar power and is used in landscaping are electrically connected in a solar array to create landscaping that generates solar power. The solar array is electrically connected to a home or business or utility grid using balance of system (BOS) components creating a solar photovoltaics power system that utilizes landscaping.

The balance of system encompasses all the components of a solar photovoltaic power system other than the pavers, artificial plants, and artificial grass. A solar photovoltaic power system utilizing a combination of pavers, artificial plants, and/or artificial grass, depending on the size of the installation, have multiple strings of solar photovoltaic array of conductive wiring/cables emanate from one or more solar arrays and terminate in one electrical box, called a fused array combiner. Contained within the combiner box are fuses designed to protect the individual array cables, as well as the connections that deliver power to the inverter. The electricity produced at this stage is DC (direct current) which is converted to AC (alternating current) for suitable use in a home or business. The inverter turns the DC electricity into 120-volt AC that can be put to immediate use by connecting the inverter directly to a dedicated circuit breaker in the electrical panel. If also tied to the utility grid, the DC power is converted into 120/240 volt AC power and fed directly into the utility power distribution system of the building.

There has thus been outlined, rather broadly, the more important features of the invention in order that the detailed description thereof may be better understood, and in order that the present contribution to the art may be better appreciated. There are additional features of the invention that will be described hereinafter and that will form the subject matter of the claims appended hereto.

In this respect, before explaining at least one embodiment of the invention in detail, it is to be understood that the invention is not limited in its application in the details of construction of the paver top and bottom surface and encasing material of the solar cells and panels and to the arrangements of the components set forth in the following description or illustrated in the drawings. It is also understood that the invention is not limited in its application in the details of construction of the solar cells or panels. It is also understood that the invention is not limited in its application in the details of construction to the configuration of the artificial grass and artificial leaf. It is also understood that the invention is not limited in its application in the details of the paver top surface material, texture, size, appearance, color, and geometry. It is also understood that the invention is not limited in its application in the details of the artificial plant structure. It is also understood that the invention is not limited in its application in the details of the artificial leaf. The invention is capable of other embodiments and of being practiced and carried out in various ways. Also, it is to be understood that the phraseology and terminology employed herein are for the purpose of the description and should not be regarded as limiting.

A primary object of the present invention is to provide a solar photovoltaics power system that is also used for landscaping.

A second object is to provide a solar photovoltaics power system that is also used for hardscaping.

Another object is to provide a solar photovoltaics power system that is also used for softscaping.

An additional object is to provide a paver that generates solar power for use in hardscaping.

A further object is to provide an artificial plant that generates solar power for use in softscaping.

Another object is to provide artificial grass that generates solar power for use in softscaping.

Other objects and advantages of the present invention will become obvious to the reader and it is intended that these objects and advantages are within the scope of the present invention.

To the accomplishment of the above and related objects, this invention may be embodied in the form illustrated in the accompanying drawings, attention being called to the fact, however, that the drawings are illustrative only, and that changes may be made in the specific construction illustrated and described within the scope of the appended claims.

### DESCRIPTION OF DRAWINGS

Various other objects, features and attendant advantages of the present invention will become fully appreciated as the same becomes better understood when considered in conjunction with the accompanying drawings, in which like reference characters designate the same or similar parts throughout the several views, and wherein:

FIG. 1 is an illustration of a solar photovoltaics power system utilizing pavers, artificial plants, and/or artificial grass in a solar array creating hardscaping, softscaping and/or landscaping.

FIG. 2 is an illustration of paver, and/or artificial plant, and/or artificial grass solar array connection to the grid and/or battery in a solar photovoltaics power system.

FIG. 3 is an illustration of a paver that generates solar power and also utilized as a hardscape.

FIG. 4 is an illustration of an artificial plant that generates solar power and also utilized as a softscape.

FIG. 5 is an illustration of artificial grass that generates solar power with the grass blade made from photovoltaic material and also utilized as a softscape.

FIG. 6 is an illustration of artificial grass that generates solar power with the grass blade made from fiber optic material and also utilized as a softscape.

### DETAILED DESCRIPTION OF THE DRAWINGS

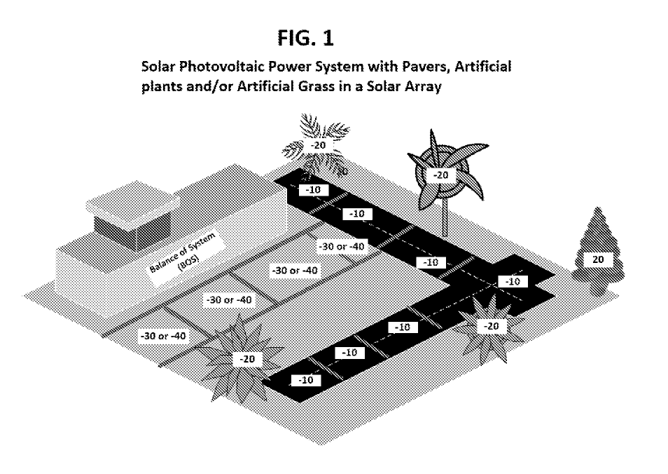

Turning now descriptively to the drawings, in which similar reference characters denote similar elements throughout the several views, FIG. 1 illustrates a solar photovoltaic power system, consisting of a plurality of pavers 10 electrically connected in a solar array, a plurality of artificial plants 20 electrically connected in a solar array, a plurality of artificial grass 30 or 40 electrically connected in a solar array, and/or any combination of pavers 10, artificial plants 20, artificial grass 30 or 40, electrically connected in a solar array. As depicted in FIG. 1, the pavers 10 are also utilized in hardscaping, the artificial plants 20 are also utilized in softscaping, and the artificial grass 30 or 40 are also utilized in softscaping. As shown in FIG. 1, the solar photovoltaic power system consist of balance of system (BOS) hardware which is utilized to connect the one or more solar arrays to the grid and/or battery.

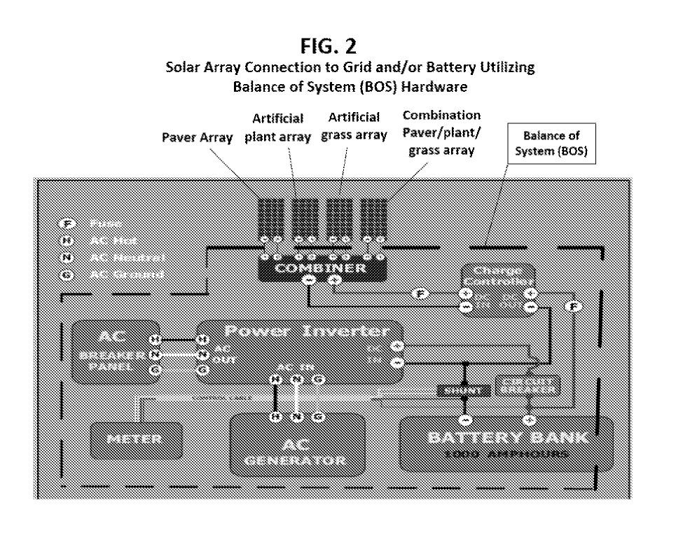

FIG. 2 illustrates a typical balance of system hardware utilized in connecting the solar arrays to the electrical grid and/or battery of a home or business.

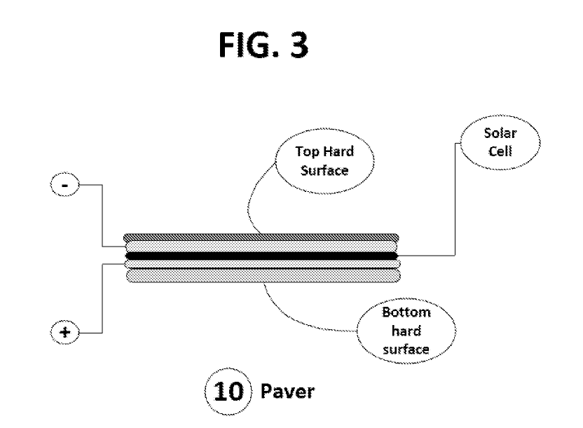

FIG. 3 illustrates a paver 10 that generates solar power consisting of one or more solar cells or solar panels sealed in anti-reflective material and adhered to a top hard surface and a bottom hard surface. The top hard surface provides support and protects the one or more solar cells or panels. The top hard surface is also manufactured from anti-reflective hard material that allows the transmission of light to the one or more solar cells or panels that lay beneath. The bottom hard surface provides support, rigidity, strength, and weight to the paver and also serves to protect the solar cells or solar panels that lay above.

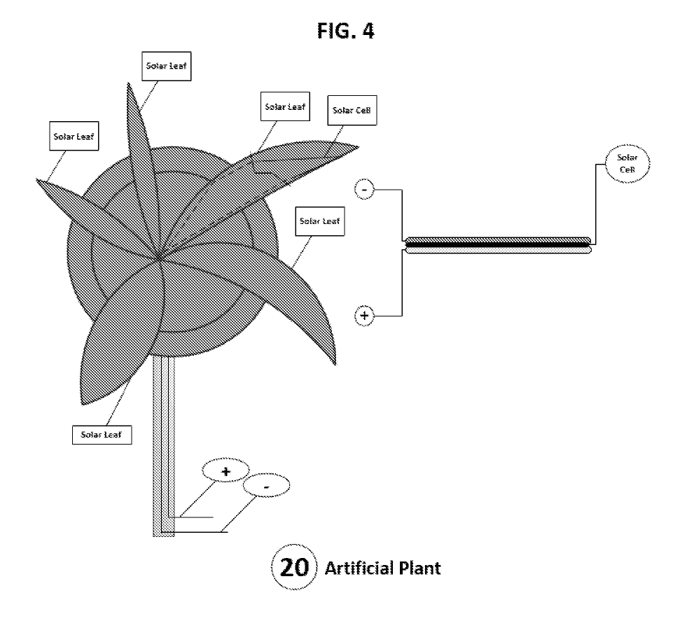

FIG. 4 illustrates an artificial plant 20 that generates solar power consisting of one or more artificial leaves that generate solar power (solar leaf). The artificial leaf consist of one or more solar cells or solar panels contained within the geometry of the artificial leaf blade or fabricated in the geometry of the artificial leaf blade. For an artificial leaf consisting of more than one solar cells or solar panels, the solar cells or solar panels are electrically connected in a solar array. Protection of the one or more solar cells or solar panels of the artificial leaf is provided by environmental sealing the artificial leaf with an anti-reflective thin film plastic material or anti-reflective sealant. As shown in FIG. 4, an artificial plant consisting of a plurality of artificial leaves that generate solar power, have the artificial leaves that generate solar power electrically connected in a solar array near the base of the stem.

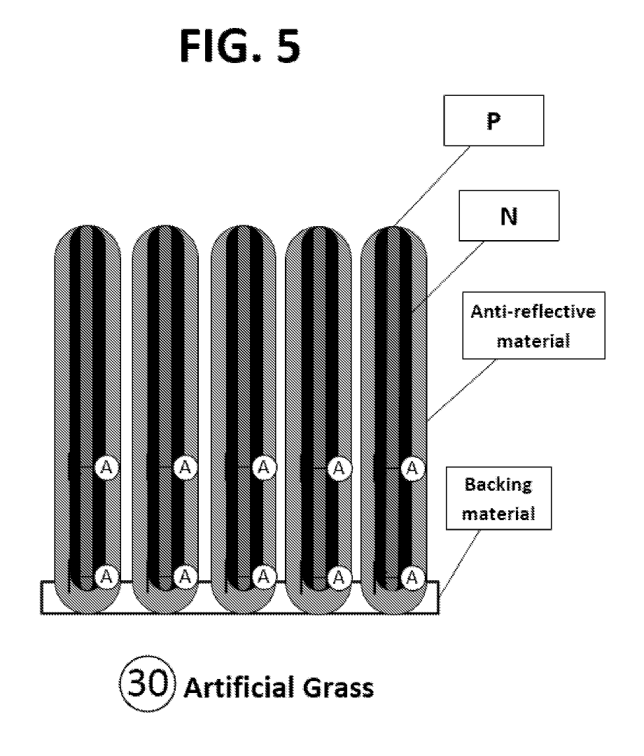

FIG. 5 illustrates artificial grass 30 that generates solar power consisting of artificial grass blades consisting of or made from one or more solar cells or solar panels electrically connected in a solar array. FIG. 5 depicts a plurality of artificial grass blades electrically connected in a solar array. As shown in FIG. 5, the solar array of grass blades are configured in a similar shape and density to resemble natural grass. The grass blades are environmentally sealed with anti-reflective thin film plastic material or anti-reflective sealant. The grass blades are adhered to backing materials which provides the solar array electrical connectivity of the blades. The backing material also provides support to the artificial grass blades.

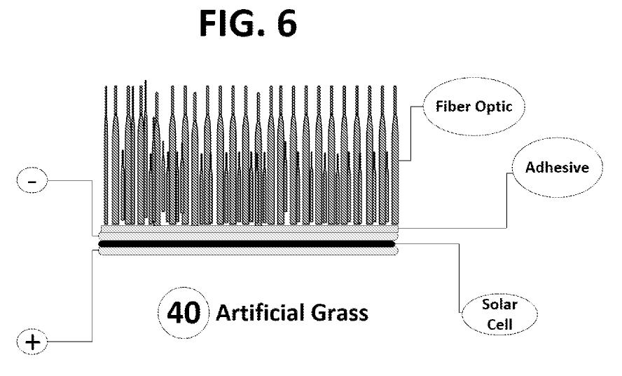

FIG. 6 illustrates artificial grass that generates solar power consisting of artificial grass blades made from fiber optic or similar light absorbent material overlaying one or more solar cells or solar panels. FIG. 6 depicts artificial grass overlaid and adhered to one or more solar cells or solar panels with a light absorbent adhesive material. As shown in FIG. 6, the grass blades are configured in a similar shape and density to resemble natural grass. The light absorbent grass blades allow for the transmission of light to the solar cells or panels that lay beneath. The light that is transmitted to the one or more solar cells or solar panels that lay beneath is able to create the photovoltaic effect and generate solar power. A plurality of solar cells or panels that lay beneath the artificial grass blades are electrically connected in a solar array.

With respect to the above description then, it is to be realized that the optimum dimensional relationships for the parts of the invention, to include variation in size, materials, shape, form, function, and manner of operation, assembly and use, are deemed to be within the expertise of those skilled in the art, and all equivalent structural variations and relationships to those illustrated in the drawings and described in the specifications are intended to be encompassed by the present invention.

While the present invention has been particularly shown and described with reference to illustrative embodiments thereof, it will be understood by those of ordinary skill in the art that various changes in form and details may be made therein without departing from the spirit and scope of the invention as defined by the appended claims. The illustrative embodiments should be considered in a descriptive sense only and not for purposes of limitation. Therefore, the scope of the invention is defined not by the detailed description of the invention but by the claims set forth in the related non-provisional application and all differences within the scope will be construed as being included in the present invention.

What is claimed:

1. A solar photovoltaics power system, comprising:
a) A paver comprising of one or more solar cells or solar panels that generates solar power and is used for hardscaping, and/or
b) An artificial plant comprising of one or more solar cells or solar panels that generates solar power and is used for softscaping, and/or
c) Artificial grass comprising of one or more solar cells or solar panels that generates solar power and is used for softscaping,
whereby a plurality of the said pavers, the said artificial plants, and/or the said artificial grass are electrically connected in a solar array and whereby the said solar array is electrically connected to a utility and/or battery using balance of system hardware.

2. A solar photovoltaics power system of claim 1, wherein a plurality of the said solar cells or the said solar panels are electrically connected in a solar array.

3. A solar photovoltaics power system of claim 1 wherein said paver further comprises a top hard surface and bottom hard surface and wherein the said one or more solar cells or solar panels is contained between the said top and bottom surface.

4. A solar photovoltaics power system of claim 3 wherein the said top hard surface is of an anti-reflective material that is efficient at absorbing solar light such as but not limited to polymer plastic material.

5. A solar photovoltaics power system of claim 3 wherein the said paver top hard surface resembles either plastic, glass, concrete, brick, stone or tile of any color, texture, or pattern.

6. A solar photovoltaics power system of claim 3 wherein said top surface and bottom surface provides structural support in its intended use as a hardscape.

7. A solar photovoltaics power system of claim 1 wherein the said paver is not limited in size or geometric shape.

8. A solar photovoltaics power system of claim 1 wherein the said one or more solar cells or solar panels is manufactured in any combination of materials in any arrangement that creates photovoltaic electricity or solar power.

9. A solar photovoltaics power system of claim 1 wherein the said artificial plant comprises of artificial leaves and wherein the said one or more solar cells or solar panels is contained within the said artificial leaf of the said artificial plant.

10. A solar photovoltaics power system of claim 9 wherein a plurality of the said artificial leaves are electrically connected in a solar array.

11. A solar photovoltaics power system of claim 9 wherein the said artificial leaf of the said artificial plant is sealed with an anti-reflective thin film plastic material or anti-reflective sealant to protect from the environment.

12. A solar photovoltaics power system of claim 1 wherein the said artificial plant resembles any natural plant.

13. A solar photovoltaics power system of claim 1 wherein the said artificial grass comprises of:
a) Artificial grass blades wherein the said one or more solar cells or solar panels is contained within the artificial grass blade of the said artificial grass and wherein a plurality of the said artificial grass blades are electrically connected in a solar array, and/or
b) Artificial grass blades wherein said artificial grass blades is manufactured out of fiber optic material or light absorbent plastic material and overlays the said one or more solar cells or solar panels and wherein the bottom of the said artificial grass blades is adhered to the top of the said one or more solar cells or solar panels by application of an adhesive and wherein a plurality of the said solar cells or said solar panels are electrically connected in a solar array.

14. A solar photovoltaics power system of claim 13 wherein the said artificial grass is sealed with an anti-reflective thin film plastic material or anti-reflective sealant.

15. A solar photovoltaics power system of claim 1 wherein the said artificial grass resembles natural grass.

16. A solar photovoltaics power system of claim 13 wherein the said artificial grass blade is manufactured with flexible and durable material.

17. A solar photovoltaics power system of claim 9 wherein the said artificial leaf is manufactured with flexible and durable material.
